(19) United States
(12) Patent Application Publication
(10) Pub. No.: US 2025/0181812 A1
(43) Pub. Date: Jun. 5, 2025

(54) SUBSTRATE DESIGN ASSISTING DEVICE, SUBSTRATE DESIGN ASSISTING SYSTEM, AND DATA STRUCTURE RELATED TO CIRCUIT INFORMATION

(71) Applicant: Murata Manufacturing Co., Ltd., Nagaokakyo-shi, (JP)

(72) Inventors: Takeshi FURUKAWA, Nagaokakyo-shi, (JP); Koshi HIMEDA, Nagaokakyo-shi, (JP); Ryoichi SASAMOTO, Nagaokakyo-shi, (JP)

(21) Appl. No.: 19/051,602

(22) Filed: Feb. 12, 2025

(30) Foreign Application Priority Data
Mar. 20, 2023 (JP) 2023-044204

(51) Int. Cl. G06F 30/392; G06F 30/31

(52) U.S. Cl. CPC G06F 30/392; G06F 30/31

(57) ABSTRACT

A substrate design assisting device that assists in arranging, on a wiring substrate, a bypass capacitor connected to a power supply line and a ground line via at least one pair of a power-side through conductor and a ground-side through conductor. The device includes a storage unit that stores circuit information representing a unit that includes a pair of a power-side through conductor and a ground-side through conductor and a capacitor element connected between the power-side through conductor and the ground-side through conductor, for each of a plurality of predetermined pitches; an input reception unit that acquires a pitch set by a user and that corresponds to one of the plurality of predetermined pitches; and a calculation unit that acquires, from the storage unit, circuit information corresponding to the pitch acquired by the input reception unit, and calculates the impedance of the supply line based on the acquired circuit information.

### CROSS REFERENCE TO RELATED APPLICATIONS

This application is a continuation of PCT Application No. PCT/JP2024/009856, filed Mar. 13, 2024, which claims priority to Japanese Patent Application No. 2023-044204, filed Mar. 20, 2023, the entire contents of each of which are hereby incorporated by reference in their entirety.

### TECHNICAL FIELD

The present invention relates to a substrate design assisting device, a substrate design assisting system, and a data structure related to circuit information.

### BACKGROUND

Japanese Unexamined Patent Application Publication No. 2015-170004 (hereinafter “JP '004”) describes the reproduction of an equivalent circuit model in a case where a single passive component has a plurality of elements in the same component. Moreover, Japanese Unexamined Patent Application Publication No. 2020-167361 (hereinafter “JP '361”) describes a multi-terminal capacitor element embedded in a substrate.

In the design of a power supply line of a wiring substrate, the layout of capacitors (for example, bypass capacitors) and inductors, as passive components, is considered at the same time as the layout of the power supply line. At this time, the transmission characteristics (e.g., the impedance characteristics) of the entire power supply line including the substrate have to be evaluated by preparing the following configurations as separate elements and combining these configurations.
An equivalent circuit model of a substrate composed of wiring lines, through conductors (such as through holes and vias), a substrate material, and the like.
A precise equivalent circuit model of a passive component (such as a capacitor, an inductor, or the like) mounted on the substrate.

Here, an actual measurement model, which forms the basis for the equivalent circuit models of “substrate” and “component”, must be able to be accurately determined. Only if the actual measurement model can be determined without being affected by measurement, it is possible to accurately express how the elements behave after connection nodes.

However, in the case of a component, such as the capacitor element described in JP '361, in which a plurality of through conductors, as extraction terminals, are connected to a single capacitor element (i.e., two electrodes with a dielectric interposed therebetween) built in a substrate, the difficulty of obtaining the actual measurement model itself increases. In particular, the difficulty increases when the XY dimension of the component itself is large.

When the actual measurement model of such a component is determined by arranging two ports like a normal two-terminal type capacitor, a capacitor component at a position relatively far from the position where the ports are arranged is observed through the internal path of the capacitor or through the wiring portion. Therefore, it is only possible to perform measurement in a state where the RL component, which is originally unrelated, on the path is added.

On the other hand, it is possible to address the above-noted problem by performing the measurement using a dedicated jig such as a substrate or socket designed to extend wiring from each terminal at the same impedance. However, unlike a general capacitor component that has a standardized size, in order to implement such a measurement method for the above-mentioned component, whose size and layout may vary depending on the customer, it is necessary to assemble the designed product to a finished product once. However, in general, the bypass capacitor required for the power supply line is selected after estimating the required impedance characteristics to some extent in advance; however, if the actual measurement model cannot be obtained until the finished product is manufactured, it is difficult to quickly meet the customer's need.

The model described in JP '004 also only reproduces the behavior of a single passive component, and the impedance of the entire substrate can only be reproduced by combining the model after designing the wiring of the wiring substrate.

### SUMMARY OF THE INVENTION

In view of the above-noted problems, it is an object of the present disclosure to provide a substrate design assisting device, a substrate design assisting system, and a data structure related to circuit information that are configured for designing a power supply line to which a bypass capacitor is connected via a plurality of through conductors.

In an exemplary aspect, a substrate design assisting device is provided that arranges, on a wiring substrate, a bypass capacitor connected to a power supply line and a ground line via at least one pair of a power-side through conductor and a ground-side through conductor. In this aspect, the substrate design assisting device includes a storage unit that stores circuit information representing a unit that includes a pair of a power-side through conductor and a ground-side through conductor and a capacitor element connected between the power-side through conductor and the ground-side through conductor, for each of a plurality of predetermined pitches between the pair of the power-side through conductor and the ground-side through conductor; an input reception unit that acquires a pitch that is set by a user, that is between at least one pair of a power-side through conductor and a ground-side through conductor, and that corresponds to one predetermined pitch of the plurality of predetermined pitches; and a calculation unit that acquires, from the storage unit, circuit information corresponding to the pitch acquired by the input reception unit, and calculates the impedance of the power supply line based on the acquired circuit information. The circuit information stored in the storage unit includes at least one of an equivalent circuit representing the unit and a parameter corresponding to at least a portion of the equivalent circuit representing the unit. The equivalent circuit representing the unit includes an equivalent circuit representing the capacitor element that includes a capacitance component set according to the corresponding predetermined pitch.

Moreover, a substrate design assisting system is provided that arranges, on a wiring substrate, a bypass capacitor connected to a power supply line and a ground line via at least one pair of a power-side through conductor and a ground-side through conductor. The substrate design assisting system includes a storage unit that stores circuit information representing a unit that includes a pair of a power-side through conductor and a ground-side through conductor and a capacitor element connected between the power-side through conductor and the ground-side through conductor, for each of a plurality of predetermined pitches between the pair of the power-side through conductor and the ground-side through conductor; an input reception unit that acquires a pitch that is set by a user, that is between at least one pair of a power-side through conductor and a ground-side through conductor, and that corresponds to one of the plurality of predetermined pitches; and a calculation unit that acquires, from the storage unit, circuit information corresponding to the pitch acquired by the input reception unit, and calculates the impedance of the power supply line based on the acquired circuit information. The circuit information stored in the storage unit includes at least one of an equivalent circuit representing the unit and a parameter corresponding to at least a portion of the equivalent circuit representing the unit. The equivalent circuit representing the unit includes an equivalent circuit representing the capacitor element, and the equivalent circuit representing the capacitor element includes a capacitance component set according to the corresponding predetermined pitch.

Yet further, a data structure is provided that is related to circuit information and that is used in a substrate design assisting device or a substrate design assisting system that comprises an input reception unit, a storage unit, and a calculation unit and that arranges, on a wiring substrate, a bypass capacitor connected to a power supply line and a ground line via at least one pair of a power-side through conductor and a ground-side through conductor. The data structure is stored in the storage unit and includes circuit information representing a unit that includes a pair of a power-side through conductor and a ground-side through conductor and a capacitor element connected between the power-side through conductor and the ground-side through conductor, for each of a plurality of predetermined pitches between the pair of the power-side through conductor and the ground-side through conductor. The data structure is used for a process in which the calculation unit acquires, based on a pitch acquired by the input reception unit, circuit information corresponding to the pitch acquired by the input reception unit from the storage unit, and calculates the impedance of the power supply line based on the acquired circuit information. The pitch that is set by the user corresponds to one of the plurality of predetermined pitches. The circuit information includes at least one of an equivalent circuit representing the unit and a parameter corresponding to at least a portion of the equivalent circuit representing the unit. The equivalent circuit representing the unit includes an equivalent circuit representing the capacitor element that includes a capacitance component set according to the corresponding predetermined pitch.

According to the exemplary aspects of the present disclosure, a substrate design assisting device, a substrate design assisting system, and a data structure related to circuit information are provided that are configured for designing a power supply line to which a bypass capacitor is connected via a plurality of through conductors.

### BRIEF DESCRIPTION OF DRAWINGS

FIG. 1 is a cross-sectional view schematically showing an example of a capacitor portion included in a wiring substrate whose design is performed with the assistance of a substrate design assisting device according to exemplary Embodiment 1.

FIG. 2A is a plan view taken along lines A and A′ of FIG. 1.

FIG. 2B is a plan view taken along lines B and B′ of FIG. 1.

FIG. 2C is a plan view taken along lines C and C′ of FIG. 1.

FIG. 2D is a plan view taken along lines D and D′ of FIG. 1.

FIG. 2E is a plan view taken along line E of FIG. 1.

FIG. 3 is a block diagram showing an example of the configuration of the substrate design assisting device according to exemplary Embodiment 1.

FIG. 4A is a diagram showing an example of an equivalent circuit representing a unit.

FIG. 4B is a diagram showing another example of an equivalent circuit representing a unit.

FIG. 5 is a diagram showing an example of equivalent circuits representing a power-side through conductor and a ground-side through conductor.

FIG. 6 is a diagram showing an example of a data structure related to circuit information stored in a storage unit when equivalent circuits representing a unit are included as the circuit information.

FIG. 7 is a diagram showing another example of a data structure related to circuit information stored in the storage unit.

FIG. 8 is a diagram showing an example of equivalent circuits representing units connected in parallel.

FIG. 9 is a diagram showing an example of an equivalent circuit representing a capacitor element.

FIG. 10A is a diagram showing an example of parameters corresponding to an equivalent circuit representing a unit.

FIG. 10B is a diagram showing another example of parameters corresponding to an equivalent circuit representing a unit.

FIG. 11 is a diagram showing another example of a parameter corresponding to an equivalent circuit representing a unit.

FIG. 12 is a diagram showing another example of a data structure related to circuit information stored in the storage unit when parameters are included as the circuit information.

FIG. 13 is a diagram showing still another example of a data structure related to circuit information stored in the storage unit when a parameter is included as the circuit information.

FIG. 14 is a diagram showing still another example of a data structure related to circuit information stored in the storage unit when an equivalent circuit and parameters are included as the circuit information.

FIG. 15 is a diagram showing still another example of a data structure related to circuit information stored in the storage unit when equivalent circuits and a parameter are included as the circuit information.

FIG. 16 is a diagram showing an example of parameters corresponding to equivalent circuits representing units connected in parallel.

FIG. 17 is a diagram showing another example of a parameter corresponding to an equivalent circuit representing units connected in parallel.

FIG. 18 is a diagram showing another example of an equivalent circuit representing a unit.

FIG. 19 is a schematic diagram showing an example of a grid and power-side through conductors and ground-side through conductors arranged at the intersections of the grid.

FIG. 20 is a schematic diagram showing another example of a grid and power-side through conductors and ground-side through conductors arranged at the intersections of the grid.

FIG. 21 is a flowchart for explaining an example of an operation of the substrate design assisting device according to exemplary Embodiment 1.

### DETAILED DESCRIPTION OF EMBODIMENTS

A substrate design assisting device, a substrate design assisting system, and a data structure related to circuit information of the present disclosure will be described below.

However, it is noted that the exemplary aspects of the present disclosure are not limited to the following configurations, and may be changed and applied as appropriate without departing from the spirit of the present disclosure. It should be noted that a combination of two or more of the individual desirable configurations described below is also included in the present disclosure.

### Exemplary Embodiment 1

In a substrate design assisting device according to the present embodiment, when at least one pair of a power-side through conductor and a ground-side through conductor is arranged on a wiring substrate by a user, a capacitor element is arranged between each pair of the through conductors at the same time. That is, when a pair of the power-side through conductor and the ground-side through conductor is arranged, a unit including the pair of the through conductors and a capacitor element connected between the pair of the through conductors is automatically set. Further, an equivalent circuit that accurately reproduces the unit including the pair of the power-side through conductor and the ground-side through conductor, specifically, an equivalent circuit including a capacitance component corresponding to the pitch between the pair of the power-side through conductor and the ground-side through conductor, is prepared in advance. Further, an equivalent circuit that accurately reproduces the scaling when a plurality of units are connected, specifically, an equivalent circuit corresponding to the number of units connected in parallel, is prepared in advance. Further, by calculating the impedance of a power supply line using such an equivalent circuit (or a parameter corresponding to the equivalent circuit), the impedance characteristics of the power supply line to which a bypass capacitor is connected via a plurality of through conductors can be accurately estimated according to the detailed design verification of the user without using an actual measurement model. In addition, the impedance characteristics of the power supply line to which a plurality of units are connected in parallel can also be accurately estimated.

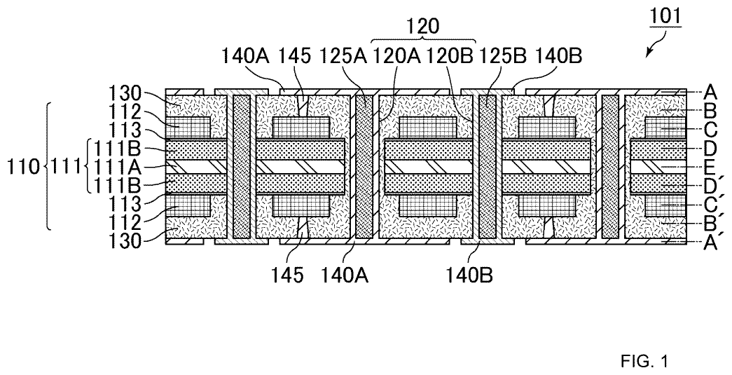

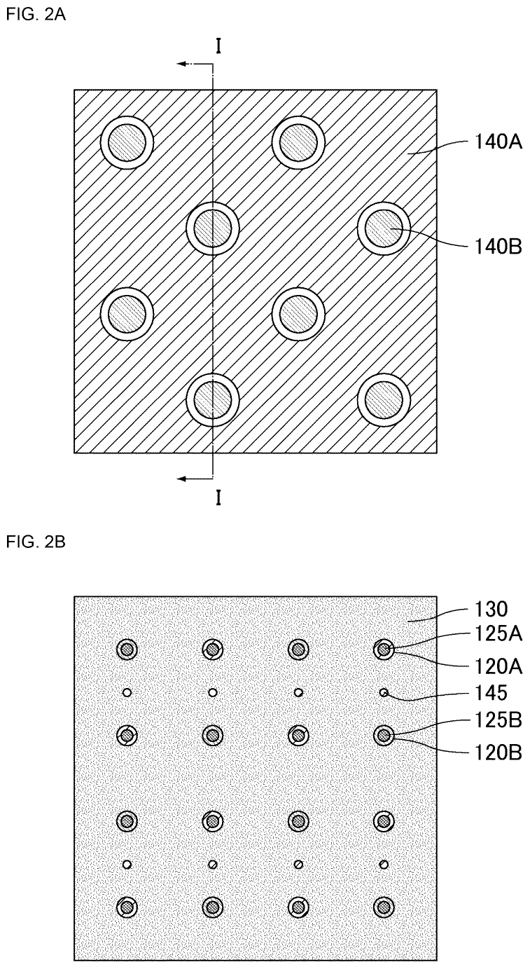

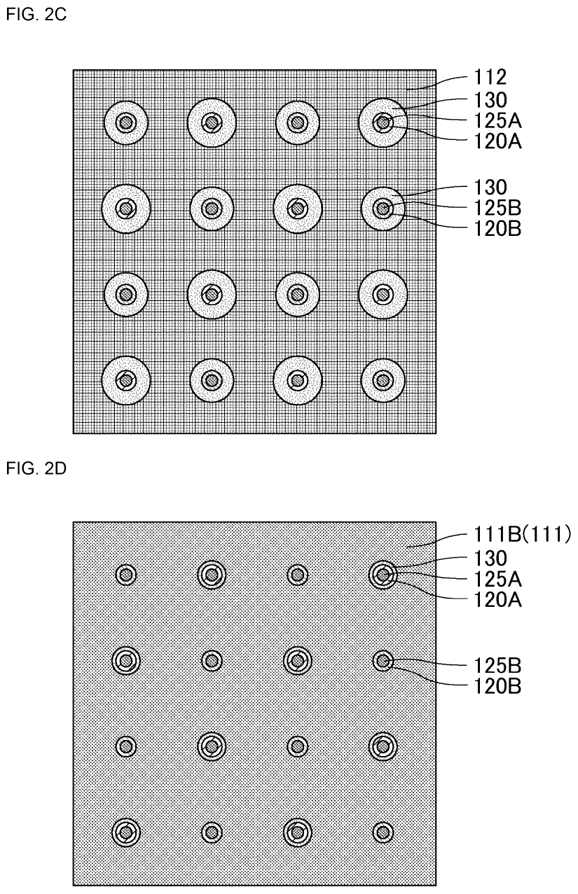

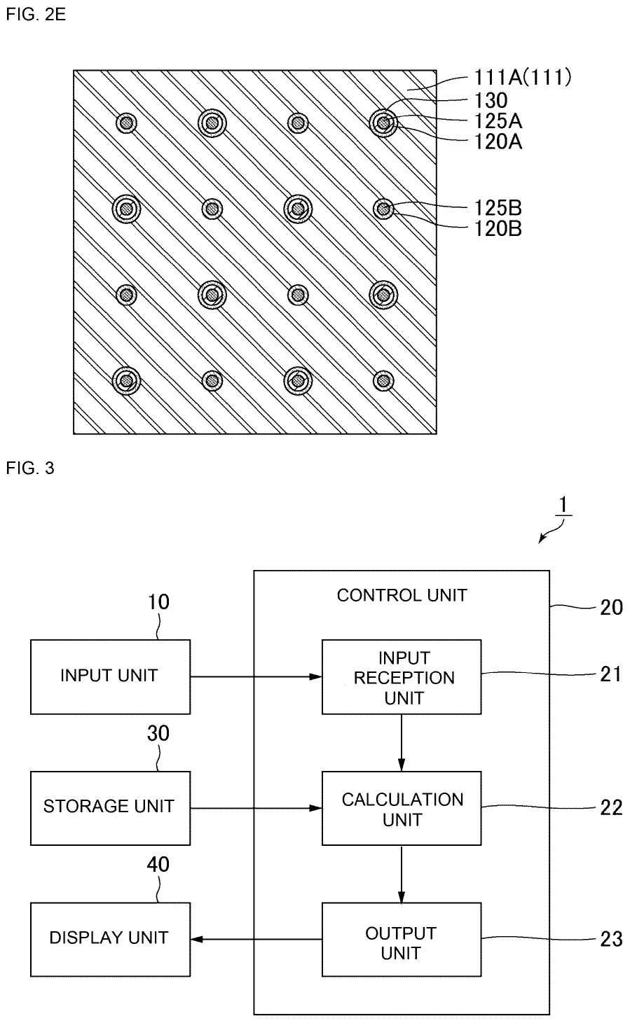

FIG. 1 is a cross-sectional view schematically showing an example of a capacitor portion included in a wiring substrate whose design is performed with the assistance of the substrate design assisting device according to exemplary Embodiment 1. FIG. 2A is a plan view taken along lines A and A′ of FIG. 1. FIG. 2B is a plan view taken along lines B and B′ of FIG. 1. FIG. 2C is a plan view taken along lines C and C′ of FIG. 1. FIG. 2D is a plan view taken along lines D and D′ of FIG. 1. FIG. 2E is a plan view taken along line E of FIG. 1. It is noted that FIG. 1 is a cross-sectional view taken along line I-I of FIG. 2A.

A capacitor portion 101 shown in FIG. 1 includes a capacitor element 110 and through conductors 120. In the example shown in FIG. 1, the capacitor portion 101 further includes a sealing layer 130 and conductor wiring layers 140A and 140B.

As shown, the capacitor element 110 includes an anode plate 111 having a porous portion 111B on at least one main surface of a core portion 111A, a dielectric layer 113 provided on the surface of the porous portion 111B, and a cathode layer 112 provided on the surface of the dielectric layer 113. Thus, the capacitor element 110 constitutes an electrolytic capacitor. In the example shown in FIG. 1, the anode plate 111 has two porous portions 111B on both main surfaces of the core portion 111A; however, the anode plate 111 may alternatively have one porous portion 111B on only one main surface of the core portion 111A.

The cathode layer 112 includes, for example, a solid electrolyte layer provided on the surface of the dielectric layer 113. Preferably, the cathode layer 112 further includes a conductive layer provided on the surface of the solid electrolyte layer. When the cathode layer 112 includes the solid electrolyte layer, the capacitor element 110 constitutes a solid electrolytic capacitor.

The through conductors 120 pass through the dielectric layer 113 and the anode plate 111 in a thickness direction (i.e., the vertical direction in FIG. 1).

The through conductors 120 include cathode through conductors 120A electrically connected to the cathode layer 112 and anode through conductors 120B electrically connected to the anode plate 111. The cathode through conductors 120A function as a ground-side through conductor connected to a ground line, and the anode through conductors 120B function as a power-side through conductor connected to a power supply line.

In the example shown in FIG. 1, a plurality of cathode through conductors 120A are provided so as to pass through the sealing layer 130 and the capacitor element 110 in the thickness direction. Each cathode through conductor 120A is connected, at its end portion, to the conductor wiring layer 140A provided on the surface of the sealing layer 130.

As shown in FIG. 2C, the cathode through conductors 120A is preferably present within the cathode layer 112 in a plan view in the thickness direction of the anode plate 111.

The cathode through conductors 120A may be provided at least on the inner wall surfaces of through holes passing through the sealing layer 130 and the capacitor element 110 in the thickness direction. That is, the cathode through conductors 120A may be provided only on the inner wall surfaces of the through holes, or they may be provided throughout the insides of the through holes. When the cathode through conductors 120A are provided only on the inner wall surfaces of the through holes, the spaces surrounded by the cathode through conductors 120A in the through holes may be filled with a material containing a resin. That is, resin filling portions 125A may be provided inside the cathode through conductors 120A.

As shown in FIG. 1, an insulating material, such as the sealing layer 130, is provided between the cathode through conductors 120A and the through holes passing through the sealing layer 130 and the capacitor element 110 in the thickness direction.

In the example shown in FIG. 1, a plurality of anode through conductors 120B are provided so as to pass through the sealing layer 130 and the capacitor element 110 in the thickness direction. Each anode through conductor 120B is connected, at its end portion, to the conductor wiring layer 140B provided on the surface of the sealing layer 130.

As shown in FIG. 2C, the anode through conductors 120B are preferably present within the cathode layer 112 in plan view in the thickness direction of the anode plate 111.

The anode through conductors 120B may be provided at least on the inner wall surfaces of through holes passing through the sealing layer 130 and the capacitor element 110 in the thickness direction. That is, the anode through conductors 120B may be provided only on the inner wall surfaces of the through holes or may be provided throughout the insides of the through holes. When the anode through conductors 120B are provided only on the inner wall surfaces of the through holes, the spaces surrounded by the anode through conductors 120B in the through holes may be filled with a material containing a resin. That is, resin filling portions 125B may be provided inside the anode through conductors 120B.

As shown in FIG. 1, the anode through conductors 120B are preferably electrically connected to the anode plate 111 at the inner wall surfaces of the through holes passing through the sealing layer 130 and the capacitor element 110 in the thickness direction. More specifically, the anode through conductors 120B are electrically connected to the end surfaces of the anode plate 111 which face the inner wall surfaces of the through holes in the planar direction. In such a case, an insulating material such as the sealing layer 130 is not provided between the anode through conductors 120B and the through holes passing through the sealing layer 130 and the capacitor element 110 in the thickness direction.

As shown in FIG. 1, the core portion 111A and the porous portion 111B are preferably exposed at the end surfaces of the anode plate 111 which are electrically connected to the anode through conductors 120B. In such a case, the porous portion 111B, in addition to the core portion 111A, is also electrically connected to the anode through conductors 120B.

As shown in FIGS. 2D and 2E, it is preferable that, when viewed in the thickness direction of the anode plate 111, the anode through conductors 120B are electrically connected to the anode plate 111 over the entire circumferences of the through holes passing through the sealing layer 130 and the capacitor element 110 in the thickness direction.

The anode through conductors 120B may be electrically connected to the anode plate 111 via an anode connection layer or may be directly connected to the end surfaces of the anode plate 111.

The sealing layer 130 is provided so as to cover the capacitor element 110. The capacitor element 110 is protected by the sealing layer 130.

As shown in FIG. 1, the sealing layer 130 is preferably provided on both main surfaces of the capacitor element 110 that are opposite to each other in the thickness direction.

The conductor wiring layers 140A and 140B are provided on the surface of the sealing layer 130 and are electrically connected to either the cathode through conductors 120A or the anode through conductors 120B.

The conductor wiring layer 140A is electrically connected to the cathode through conductors 120A. In the example shown in FIG. 1, the conductor wiring layer 140A is provided on the surface of the cathode through conductors 120A and functions as a connection terminal of the capacitor portion 101.

Specifically, in the example shown in FIG. 1, the conductor wiring layer 140A is electrically connected to the cathode layer 112 through via conductors 145 passing through the sealing layer 130, and functions as a connection terminal for the cathode layer 112.

The conductor wiring layers 140B are electrically connected to the anode through conductors 120B. In the example shown in FIG. 1, the conductor wiring layers 140B are provided on the surfaces of the anode through conductors 120B and function as a connection terminal of the capacitor portion 101.

Specifically, in the example shown in FIG. 1, the conductor wiring layers 140B are electrically connected to the anode plate 111 via the anode through conductors 120B, and function as a connection terminal for the anode plate 111.

In the exemplary aspect, a ground line (not shown) provided on an insulating layer (not shown) covering the conductor wiring layers 140A and 140B is electrically connected, via a via conductor (not shown) passing through the insulating layer, to the conductor wiring layer 140A, so that the ground line is electrically connected to the cathode layer 112 of the capacitor element 110 via the cathode through conductors 120A. On the other hand, a power supply line (not shown) provided on the insulating layer covering the conductor wiring layers 140A and 140B is electrically connected, via a via conductor (not shown) passing through the insulating layer, to the conductor wiring layers 140B, so that the power supply line is electrically connected to the anode plate 111 of the capacitor element 110 via the anode through conductors 120B.

FIG. 3 is a block diagram showing an example of the configuration of the substrate design assisting device according to exemplary Embodiment 1.

A substrate design assisting device 1 shown in FIG. 3 is a device that assists in designing a wiring substrate; the substrate design assisting device 1 assists in arranging, on the wiring substrate, a bypass capacitor connected to a power supply line and a ground line via at least one pair of a power-side through conductor and a ground-side through conductor.

The substrate design assisting device 1 includes an input unit 10, a control unit 20, a storage unit 30, and a display unit 40.

The input unit 10 is composed of, for example, a keyboard, a mouse, and the like, and the display unit 40 is composed of, for example, a liquid crystal display or the like. The substrate design assisting device 1 is configured so that a user (such as the designer of the wiring substrate) can design (e.g., draw) the wiring substrate by operating the input unit 10 while checking an image displayed on the display unit 40.

The control unit 20 is configured as a computer system including a CPU (Central Processing Unit) and the like. The control unit 20 implements, at the CPU, various processes by executing predetermined software programs stored in the storage unit 30.

In the exemplary aspect, the storage unit 30 is composed of storage devices such as a RAM (Random Access Memory), a ROM (Read Only Memory), and a hard disk, and stores various programs and information (data) for controlling the substrate design assisting device 1. For example, a design assisting program, which is software for assisting the design of the wiring substrate, is stored as one of the programs.

The storage unit 30 is configured to store a data structure related to circuit information; the data structure has circuit information for each of a plurality of predetermined pitches between a pair of the power-side through conductor and the ground-side through conductor, the circuit information representing a unit that includes the pair of the power-side through conductor and the ground-side through conductor and a capacitor element connected between the power-side through conductor and ground-side through conductor. For purposes of this disclosure, the term “predetermined pitch” means a predetermined pitch between a pair of the power-side through conductor and the ground-side through conductor included in the unit.

More specifically, the circuit information includes an equivalent circuit representing a unit (referred to as “unit equivalent circuit” hereinafter), the unit equivalent circuit includes an equivalent circuit representing a capacitor element included in the unit (referred to as “capacitor equivalent circuit” hereinafter), and the capacitor equivalent circuit includes a capacitance component set according to a corresponding predetermined pitch. That is, the storage unit 30 is configured to store a plurality of unit equivalent circuits that are preset (e.g., prepared) corresponding to a plurality of predetermined pitches. The capacitance component included in the capacitor equivalent circuit is set according to the predetermined pitch corresponding to the capacitance.

Here, the predetermined pitch is a preset pitch between a pair of the power-side through conductor and the ground-side through conductor included in the unit, in which the preset pitch can be selected in the substrate design assisting device 1. The number of predetermined pitches is not particularly limited, but can be set appropriately as long as it is 2 or more.

Note that the data structure related to circuit information may be introduced in the substrate design assisting device 1 in advance, or may be provided to the user on a computer-readable recording medium or via a network. Further, the data structure related to circuit information may be incorporated together with add-ins into a general-purpose design assisting program, such as a process design kit.

In an exemplary aspect, the unit equivalent circuit preferably includes an inductance component representing the power-side through conductor and an inductance component representing the ground-side through conductor, which are set regardless of the predetermined pitch. Thus, the calculation accuracy of the impedance of the power supply line can be improved. That is, it is preferable that the equivalent circuit representing the power-side through conductor and the equivalent circuit representing the ground-side through conductor each include at least an inductance component common to all the predetermined pitches (i.e., the same inductance).

Thus, the unit equivalent circuit preferably includes an equivalent circuit representing the power-side through conductor and an equivalent circuit representing the ground-side through conductor.

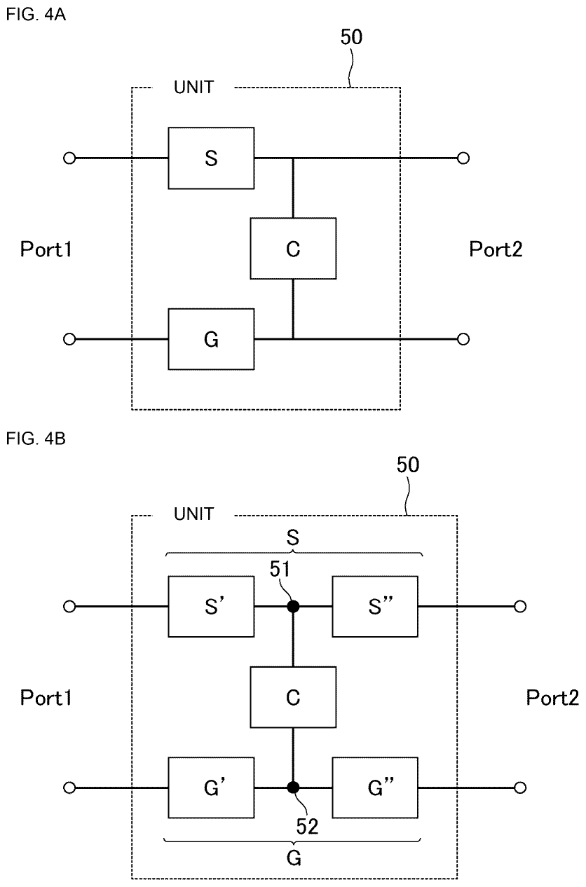

FIG. 4A is a diagram showing an example of an equivalent circuit representing a unit.

A unit equivalent circuit 50 shown in FIG. 4A includes an equivalent circuit S representing the power-side through conductor connected to the power supply line, an equivalent circuit G representing the ground-side through conductor connected to the ground line, and a capacitor equivalent circuit C connected between the equivalent circuits S and G. The capacitor equivalent circuit C is connected to nodes of the equivalent circuits S and G on an output port (Port 2) side. A power supply and a ground are connected to an input port (Port 1), and a load such as a CPU is connected to the output port (Port 2). The unit equivalent circuit 50 shows a case where a capacitor element is formed only on one of the front and rear sides of the anode plate.

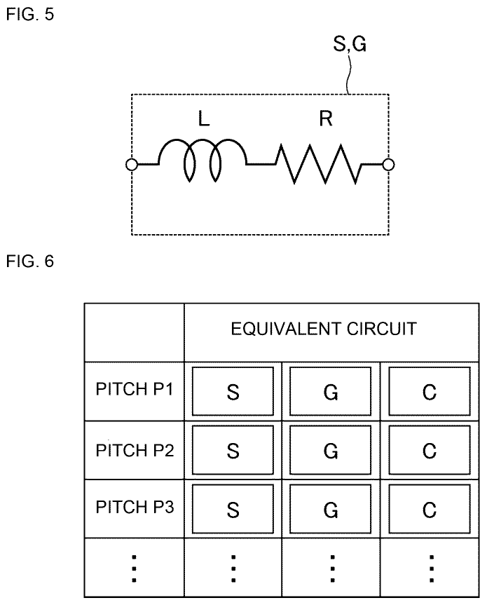

FIG. 5 is a diagram showing an example of equivalent circuits representing a power-side through conductor and a ground-side through conductor.

As shown in FIG. 5, the equivalent circuit S representing the power-side through conductor and the equivalent circuit G representing the ground-side through conductor each include an inductance component L and a resistance component R connected in series. The inductance component L is connected to the input port (Port 1), and the resistance component R is connected to the output port (Port 2) (see FIG. 4A).

Here, the inductance component L and the resistance component R are set regardless of the predetermined pitch. That is, an inductance and a resistance that are commonly used for all predetermined pitches (i.e., the same inductance and the same resistance) are set. In the substrate design assisting device 1, a design rule is set, and a circuit design is performed. The diameter, the plating thickness, and the material of the through conductors and the thickness (=through hole length) of the resin substrate through which connections are to be made are also set when the circuit design is performed. Therefore, when it is indicated which layers are to be connected by the through conductors, the inductance component L and the resistance component R for that part are theoretically determined. The material of the through conductors is generally Cu, but not limited to Cu, and the resistance component R is assigned corresponding to the set wiring type.

In an exemplary aspect, the equivalent circuit representing the power-side through conductor preferably includes a first circuit portion and a second circuit portion connected in series between the input port and the output port, the equivalent circuit representing the ground-side through conductor include a third circuit portion and a fourth circuit portion connected in series between the input port and the output port, and the capacitor equivalent circuit be connected to a node between the first circuit portion and the second circuit portion and a node between the third circuit portion and the fourth circuit portion. Thus, since each component of each circuit portion on the output port side can be set in consideration of the reflection characteristics on the output port side, the accuracy of substrate design assistance can be further improved.

FIG. 4B is a diagram showing another example of an equivalent circuit representing a unit.

The unit equivalent circuit 50 may be the one illustrated in FIG. 4B, instead of the one illustrated in FIG. 4A. In such a case, the equivalent circuit S representing the power-side through conductor includes a first circuit portion S′ and a second circuit portion S″ connected in series between the input port (Port 1) and the output port (Port 2), the equivalent circuit G representing the ground-side through conductor includes a third circuit portion G′ and a fourth circuit portion G″ connected in series between the input port (Port 1) and the output port (Port 2), and the capacitor equivalent circuit C is connected to a node 51 between the first circuit portion S′ and the second circuit portion S″ and a node 52 between the third circuit portion G′ and the fourth circuit portion G″. Here, the components of the second circuit portion S″ and the fourth circuit portion G″ on the output port (Port 2) side are set in consideration of the reflection characteristics on the output port (Port 2) side. Therefore, at least some components of the first circuit portion S′ and the second circuit portion S″ may differ from each other, and similarly, at least some components of the third circuit portion G′ and the fourth circuit portion G″ may differ from each other.

Note that the first circuit portion S′, the second circuit portion S″, the third circuit portion G′, and the fourth circuit portion G″ each include the inductance component L and the resistance component R connected in series, as shown in FIG. 5. In each circuit portion, the inductance component L is located on the input port (Port 1) side, and the resistance component R is located on the output port (Port 2) side. In the unit equivalent circuit 50 illustrated in FIG. 4B, the inductance component L and resistance component R are also set regardless of the predetermined pitch.

FIG. 6 is a diagram showing an example of a data structure related to circuit information stored in the storage unit when equivalent circuits representing a unit are included as the circuit information.

As shown in FIG. 6, the storage unit 30 stores a unit equivalent circuit for each of the predetermined pitches P1, P2, P3, . . . between a pair of the power-side through conductor and the ground-side through conductor. However, the equivalent circuit S representing the power-side through conductor and the equivalent circuit G representing the ground-side through conductor are common to each predetermined pitch. It is noted that in this description, the expression that two equivalent circuits are common or equivalent means that the type, number, connection, and values (such as capacitance, inductance, resistance, and the like) of the constituent elements (e.g., components) are the same. On the other hand, the capacitor equivalent circuit C includes a capacitance component set separately and independently for each predetermined pitch. It is also noted that a plurality of capacitance components set corresponding to different predetermined pitches usually have different capacitances from each other, but a plurality of capacitance components having the same capacitance may be included.

The storage unit 30 stores circuit information representing the units according to the number of units connected in parallel. That is, the storage unit 30 stores the unit equivalent circuit, as circuit information, for each of the units connected in parallel to the same power supply line.

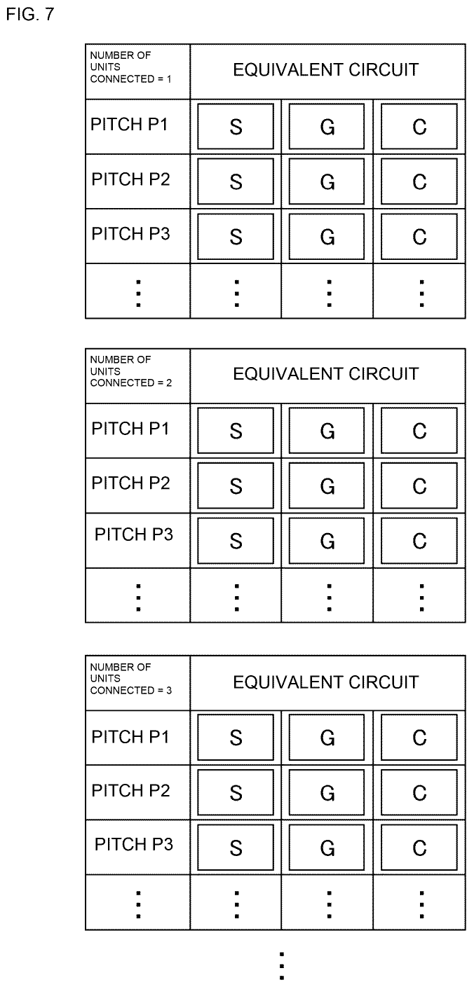

FIG. 7 is a diagram showing another example of a data structure related to circuit information stored in the storage unit.

As shown in FIG. 7, the storage unit 30 stores a unit equivalent circuit for each number of units connected. However, the equivalent circuit S representing the power-side through conductor and the equivalent circuit G representing the ground-side through conductor are common to each number of units connected. On the other hand, the capacitor equivalent circuit C includes a capacitance component set separately and independently for each number of units connected. It is noted that a plurality of capacitance components set corresponding to different numbers of units connected usually have different capacitances from each other, but a plurality of capacitance components having the same capacitance may be included.

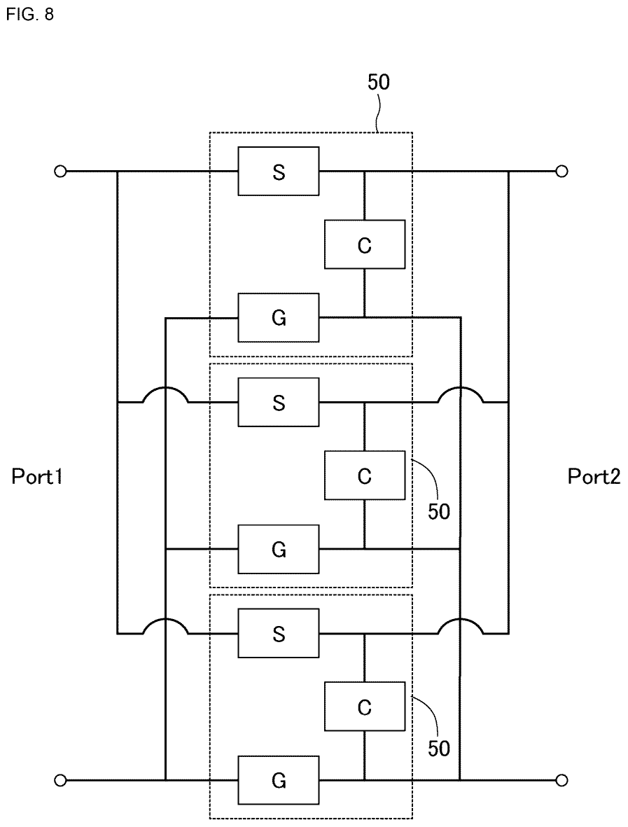

FIG. 8 is a diagram showing an example of equivalent circuits representing units connected in parallel.

The equivalent circuits shown in FIG. 8 represent a plurality of units, in this case three units, connected in parallel to the same power supply line. The unit equivalent circuits 50 shown in FIG. 4A are connected in parallel between the input port (Port 1) and the output port (Port 2). In such a case, the capacitor equivalent circuit C of each unit equivalent circuit 50 includes a common capacitance component corresponding to the predetermined pitch and the number of units connected (=3).

It is noted that although FIG. 8 shows a case where all of the unit equivalent circuits 50 connected in parallel are those illustrated in FIG. 4A, at least one of these unit equivalent circuits 50 may be the one illustrated in FIG. 4B.

It is preferable that the capacitor equivalent circuit include a ladder circuit. Thus, it is possible to reproduce a capacitor element built in a substrate and connected to a plurality of through conductors, as extraction terminals, with higher accuracy.

From the viewpoint of calculation accuracy, the ladder circuit preferably includes two or more capacitance components set according to the corresponding predetermined pitch.

Thus, the ladder circuit includes a plurality of capacitance components connected in parallel with each other, and the capacitance of the plurality of capacitance components is set according to the corresponding predetermined pitch.

The upper limit of the number of capacitance components included in the ladder circuit is not particularly limited, but can be set appropriately; preferably, the number of capacitance components is 5 or less, and more preferably 4 or less. This is because the effect of improving calculation accuracy by the ladder circuit tends to become saturated as the number of capacitance components increases.

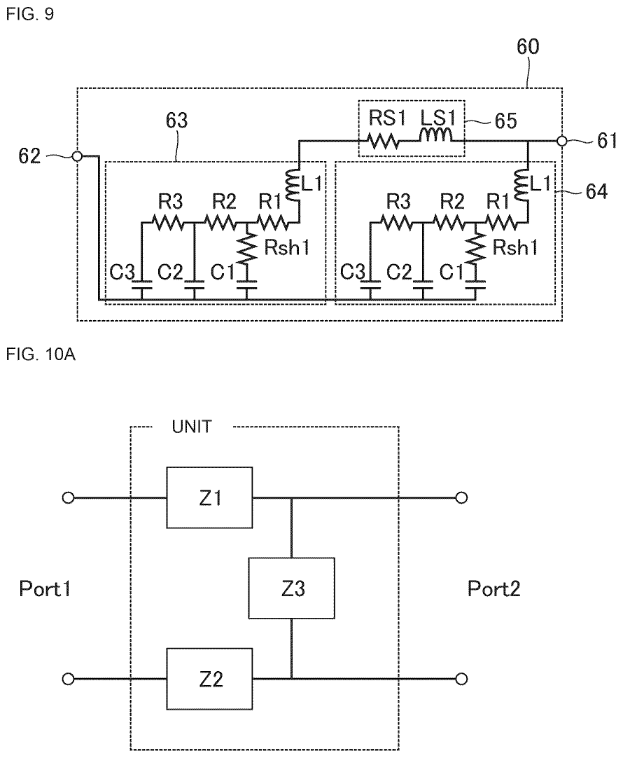

FIG. 9 is a diagram showing an example of an equivalent circuit representing a capacitor element.

A capacitor equivalent circuit 60 shown in FIG. 9 includes a first terminal 61 connected to the power-side through conductor, a second terminal 62 connected to the ground-side through conductor, a first capacitance portion 63, a second capacitance portion 64, and an LR circuit 65 connected between the first terminal 61 and the first capacitance portion 63.

The first capacitance portion 63 and the second capacitance portion 64 are equivalent to each other. That is, the first capacitance portion 63 and the second capacitance portion 64 are composed of the same RLC components. The first capacitance portion 63 and the second capacitance portion 64 are connected in parallel between the first terminal 61 and the second terminal 62.

The first capacitance portion 63 and the second capacitance portion 64 are each composed of three capacitance components C1, C2, and C3, four resistance components R1, R2, R3, and Rsh1, and an inductance component L1. The three capacitance components C1, C2, and C3 and the three resistance components R1, R2, and R3 are connected in a ladder shape. The resistance component Rsh1 is connected between the capacitance component C1 and the resistance component R1 at the first stage. The inductance component L1 is connected to the resistance component R1 at the first stage.

The LR circuit 65 is an LR series circuit composed of a resistance component RS1 and an inductance component LS1 connected in series. Thus, the capacitor equivalent circuit 60 includes an equivalent circuit portion (an equivalent circuit composed of the first capacitance portion 63 and the LR circuit 65) that reaches the capacitance components C1, C2, and C3 after passing through the LR circuit 65.

Here, the capacitance components C1, C2, and C3 are set for each predetermined pitch. The other components, namely, the resistance components R1, R2, R3, and Rsh1 and the inductance component L1, are also set for each predetermined pitch. That is, components (e.g., capacitance, resistance, and/or inductance) that vary depending on the predetermined pitch are set for each component.

Each capacitance component, each inductance component, and each resistance component included in the capacitor equivalent circuit 60 are determined based on actual measured data. As described in the discussion the above problem, when the number of units connected increases, the characteristics are observed in a state where the RL component of the wiring portion is added; therefore, the scaling effect is confirmed at the number of units connected where the above effect is negligible, and each multiplier which most closely matches the actually measured value and structural feature is set as the corresponding component, and the circuit thus obtained is defined as the capacitor equivalent circuit 60.

In an exemplary aspect, the circuit information stored in the storage unit 30 may include, instead of the unit equivalent circuit, a parameter corresponding to at least a portion of the unit equivalent circuit (referred to hereinafter as “alternative parameter”), or may include both the unit equivalent circuit and the alternative parameter.

Specific examples of the alternative parameter include the frequency characteristics of impedance and the S parameter of the corresponding unit equivalent circuit or capacitor equivalent circuit. The alternative parameter may be calculated from the corresponding unit equivalent circuit or capacitor equivalent circuit or may be set directly based on actual measurement.

FIG. 10A is a diagram showing an example of parameters corresponding to an equivalent circuit representing a unit.

The alternative parameters shown in FIG. 10A correspond to the unit equivalent circuit 50 shown in FIG. 4A, and are obtained by replacing the equivalent circuit S representing the power-side through conductor, the equivalent circuit G representing the ground-side through conductor and the capacitor equivalent circuit C shown in FIG. 4A with alternative parameters Z1, Z2, and Z3 corresponding to the equivalent circuit S, the equivalent circuit G and the capacitor equivalent circuit C, respectively. Therefore, the connection relationship of each alternative parameter is the same as that shown in FIG. 4A.

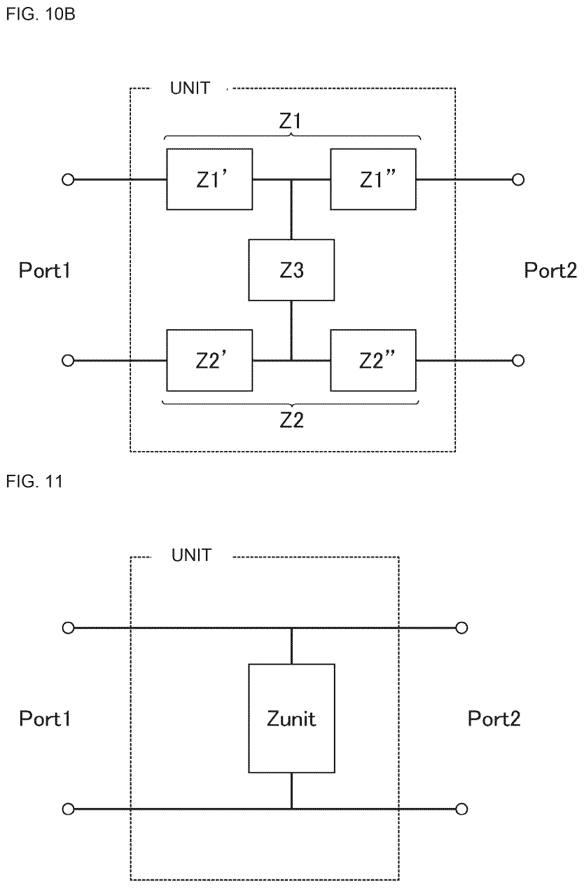

FIG. 11 is a diagram showing another example of a parameter corresponding to an equivalent circuit representing a unit.

The alternative parameter shown in FIG. 11 also corresponds to the unit equivalent circuit 50 shown in FIG. 4A, but is obtained by replacing the equivalent circuit S representing the power-side through conductor, the equivalent circuit G representing the ground-side through conductor and the capacitor equivalent circuit C shown in FIG. 4A with an alternative parameter Zunit corresponding to an equivalent circuit of the total of the equivalent circuit S, the equivalent circuit G and the capacitor equivalent circuit C. Therefore, the alternative parameter Zunit is a parameter set in consideration of the equivalent circuit S representing the power-side through conductor and the equivalent circuit G representing the ground-side through conductor.

FIG. 10B is a diagram showing another example of parameters corresponding to an equivalent circuit representing a unit.

The alternative parameters shown in FIG. 10B correspond to the unit equivalent circuit 50 shown in FIG. 4B, and are obtained by replacing the first circuit portion S′ and the second circuit portion S″ of the equivalent circuit S representing the power-side through conductor shown in FIG. 4B with alternative parameters Z1′ and Z1″ corresponding to the first circuit portion S′ and the second circuit portion S″, respectively, replacing the third circuit portion G′ and the fourth circuit portion G″ of the equivalent circuit G representing the ground-side through conductor shown in FIG. 4B with alternative parameters Z2′ and Z2″ corresponding to the third circuit portion G′ and the fourth circuit portion G″, respectively, and replacing the capacitor equivalent circuit C shown in FIG. 4B with an alternative parameter Z3 corresponding to the capacitor equivalent circuit C. Therefore, the connection relationship of each alternative parameter is the same as that shown in FIG. 4B. Here, the alternative parameters Z1″ and Z2″ on the output port (Port 2) side are set in consideration of the reflection characteristics on the output port (Port 2) side. Therefore, the accuracy of substrate design assistance can be further improved.

It is noted that the alternative parameter Zunit shown in FIG. 11 may correspond to the unit equivalent circuit 50 shown in FIG. 4B. That is, the alternative parameter Zunit shown in FIG. 11 may be equivalent to the alternative parameter shown in FIG. 10B.

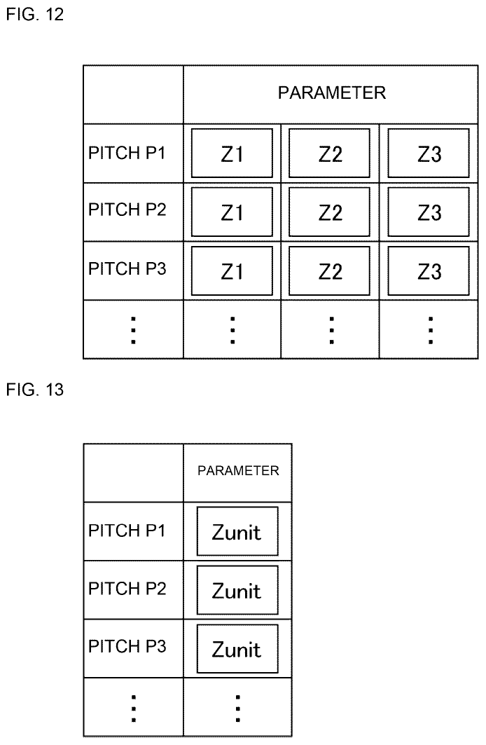

FIG. 12 is a diagram showing another example of a data structure related to circuit information stored in the storage unit when parameters are included as the circuit information.

As shown in FIG. 12, the storage unit 30 may store the alternative parameter Z1 corresponding to the equivalent circuit representing the power-side through conductor, the alternative parameter Z2 corresponding to the equivalent circuit representing the ground-side through conductor, and the alternative parameter Z3 corresponding to the capacitor equivalent circuit for each predetermined pitch. However, the alternative parameter Z1 corresponding to the equivalent circuit representing the power-side through conductor is common to each predetermined pitch, and the alternative parameter Z2 corresponding to the equivalent circuit representing the ground-side through conductor is also common to each predetermined pitch. On the other hand, the alternative parameter Z3 corresponding to the capacitor equivalent circuit reflects the capacitance component of the capacitor equivalent circuit set separately and independently for each predetermined pitch. It is noted that in this description, the expression that two alternative parameters are common means that the alternative parameters correspond to two equivalent circuits that are equivalent to each other.

In an exemplary aspect, the alternative parameters Z1′ and Z1″ corresponding to the first circuit portion S′ and the second circuit portion S″, respectively, of the equivalent circuit S representing a power-side through conductor are also common to each predetermined pitch, and the alternative parameters Z2′ and Z2″ corresponding to the third circuit portion G′ and the fourth circuit portion G″, respectively, of the equivalent circuit G representing a ground-side through conductor are also common to each predetermined pitch.

In addition, the alternative parameters Z1′ and Z1″ shown in FIG. 10B may be stored instead of at least one of the alternative parameters Z1 shown in FIG. 12. Similarly, the alternative parameters Z2′ and Z2″ shown in FIG. 10B may be stored instead of at least one of the alternative parameters Z2 shown in FIG. 12.

FIG. 13 is a diagram showing still another example of a data structure related to circuit information stored in the storage unit when a parameter is included as the circuit information.

As shown in FIG. 13, the storage unit 30 may store, for each predetermined, the alternative parameter Zunit that corresponds to the total of the equivalent circuit representing the power-side through conductor, the equivalent circuit representing the ground-side through conductor, and the capacitor equivalent circuit. Therefore, the alternative parameter Zunit reflects the capacitance component of the capacitor equivalent circuit set separately and independently for each predetermined pitch.

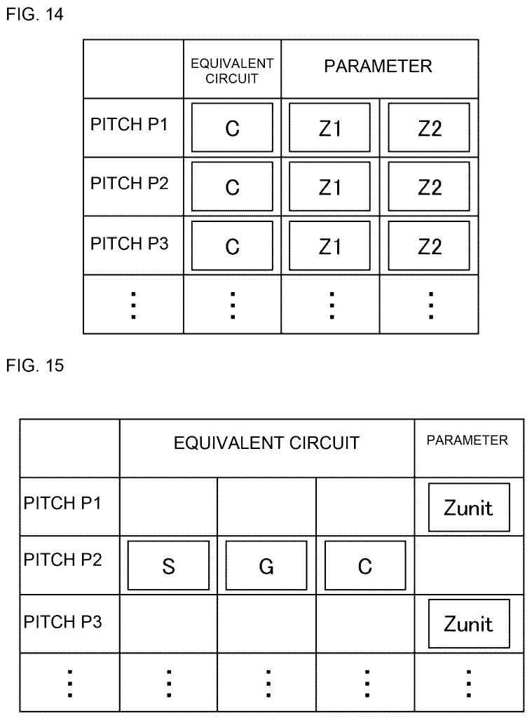

FIG. 14 is a diagram showing still another example of a data structure related to circuit information stored in the storage unit when an equivalent circuit and parameters are included as the circuit information.

As shown in FIG. 14, the storage unit 30 may store, for each predetermined pitch, a portion of the unit equivalent circuit (for example, the capacitor equivalent circuit C), and alternative parameters (for example, the alternative parameters Z1 and Z2) corresponding to the remaining portion of the unit equivalent circuit (for example, the equivalent circuit representing a power-side through conductor and the equivalent circuit representing a ground-side through conductor).

In addition, the alternative parameters Z1′ and Z1″ shown in FIG. 10B may be stored instead of at least one of the alternative parameters Z1 shown in FIG. 14. Similarly, the alternative parameters Z2′ and Z2″ shown in FIG. 10B may be stored instead of at least one of the alternative parameters Z2 shown in FIG. 14.

FIG. 15 is a diagram showing still another example of a data structure related to circuit information stored in the storage unit when equivalent circuits and a parameter are included as the circuit information.

As shown in FIG. 15, the storage unit 30 may store the unit equivalent circuits corresponding to one or more predetermined pitches and the alternative parameter Zunit (corresponding to the total of the unit equivalent circuits) corresponding to the other one or more predetermined pitches.

Alternatively, the storage unit 30 may appropriately combine the circuit information shown in FIG. 6 and FIGS. 12 to 15 and store the combination.

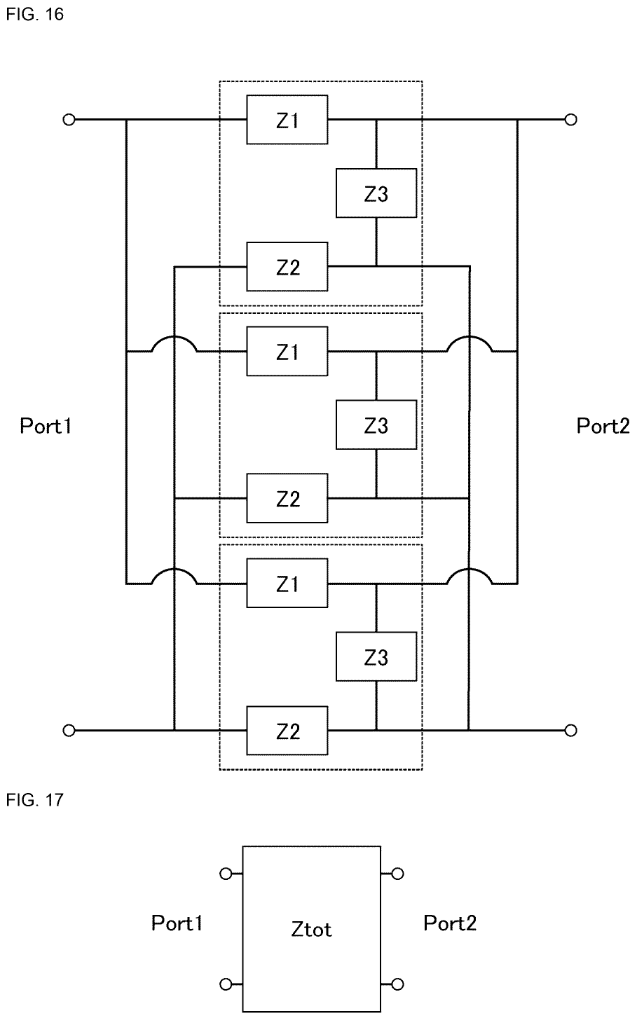

FIG. 16 is a diagram showing an example of parameters corresponding to equivalent circuits representing units connected in parallel.

The alternative parameters shown in FIG. 16 correspond to the equivalent circuits representing the units connected in parallel shown in FIG. 8, and are obtained by replacing the equivalent circuit S representing the power-side through conductor, the equivalent circuit G representing the ground-side through conductor, and the capacitor equivalent circuit C shown in FIG. 8 with the alternative parameters Z1, Z2, and Z3 corresponding to the equivalent circuit S, the equivalent circuit G, and the capacitor equivalent circuit C, respectively. Therefore, the connection relationship of each alternative parameter is the same as that shown in FIG. 8.

Although FIG. 16 shows a case where all of the alternative parameters connected in parallel are those illustrated in FIG. 10A, at least one of these alternative parameters may be the one illustrated in FIG. 10B.

FIG. 17 is a diagram showing another example of a parameter corresponding to an equivalent circuit representing units connected in parallel.

The alternative parameter shown in FIG. 17 also corresponds to the equivalent circuit representing the units connected in parallel shown in FIG. 8, but is obtained by replacing the equivalent circuit of the total of the three unit equivalent circuits 50 shown in FIG. 8 with an alternative parameter Ztot that corresponds to the equivalent circuit of the total of the three unit equivalent circuits 50 shown in FIG. 8.

The alternative parameter Ztot shown in FIG. 17 may correspond to an equivalent circuit in which at least one of the unit equivalent circuits 50 shown in FIG. 8 is the one illustrated in FIG. 4B.

In an exemplary aspect, the unit equivalent circuit preferably includes, as the capacitor equivalent circuit, a first equivalent circuit representing a first capacitor element and a second equivalent circuit representing a second capacitor element, that the first equivalent circuit and the second equivalent circuit be equivalent to each other, that the first equivalent circuit be connected to a node of the power-side through conductor on one main surface (e.g., a first main surface) side of the wiring substrate and a node of the ground through conductor on the one main surface (the first main surface) side of the wiring substrate, and that the second equivalent circuit be connected to a node of the power-side through conductor on the other main surface (e.g., a second main surface) side of the wiring substrate and a node of the ground through conductor on the other main surface (the second main surface) side of the wiring substrate. Thus, it is possible to accurately reproduce a case where the unit includes, as the capacitor element, the first capacitor element and the second capacitor element connected in parallel between a pair of the power-side through conductor and the ground-side through conductor. The first capacitor element and the second capacitor element are arranged independently on the front and rear sides of the anode plate.

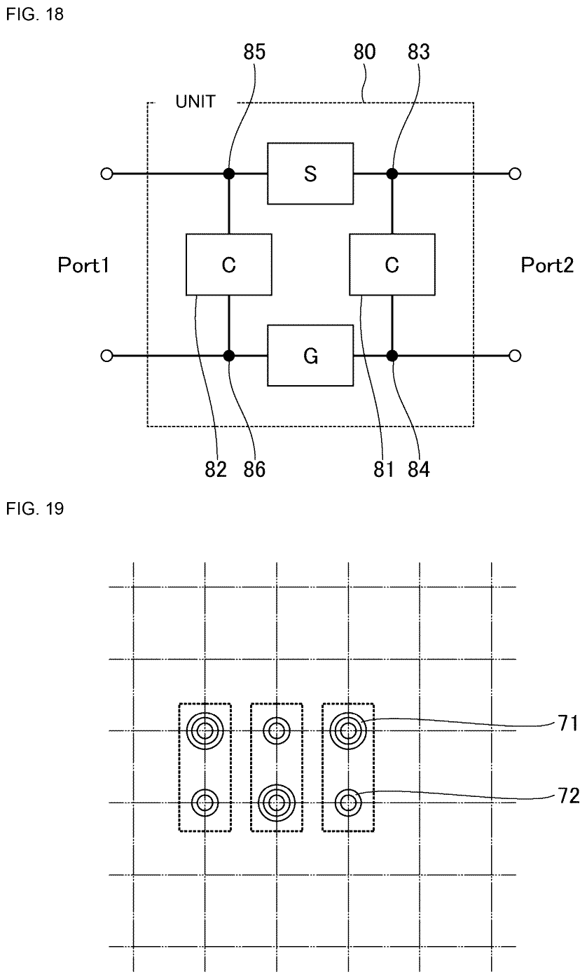

FIG. 18 is a diagram showing another example of an equivalent circuit representing a unit.

A unit equivalent circuit 80 shown in FIG. 18 includes an equivalent circuit S representing a power-side through conductor connected to a power supply line, an equivalent circuit G representing a ground-side through conductor connected to a ground line, and two capacitor equivalent circuits C connected between the equivalent circuits S and G. One of the two capacitor equivalent circuits C is a first equivalent circuit 81 representing a first capacitor element and is connected to a node 83 of the equivalent circuit S on an output port (Port 2) side and a node 84 of the equivalent circuit G on the output port (Port 2) side. The other of the two capacitor equivalent circuits C is a second equivalent circuit 82 representing a second capacitor element and is connected to a node 85 of the equivalent circuit S on an input port (Port 1) side and a node 86 of the equivalent circuit G on the input port (Port 1) side. The unit equivalent circuit 80 is obtained by adding a capacitor equivalent circuit C to the input port (Port 1) side of the equivalent circuits S and G of the unit equivalent circuit 50 shown in FIG. 4A. The unit equivalent circuit 80 represents a case where the first and second capacitor elements are formed on both the front and rear sides of the anode plate.

The first equivalent circuit 81 and the second equivalent circuit 82 are the same as the capacitor equivalent circuit 60 shown in FIG. 9 and are equivalent to each other. That is, the first equivalent circuit 81 and the second equivalent circuit 82 are composed of the same RLC components. The first terminal 61 shown in FIG. 9 is connected to the node 83 or 85, and the second terminal 62 shown in FIG. 9 is connected to the node 84 or 86.

The first equivalent circuit 81 is connected to a node of the power-side through conductor on one main surface side of the wiring substrate and a node of the ground through conductor on the one main surface side of the wiring substrate, and the second equivalent circuit 82 is connected to a node of the power-side through conductor on the other main surface side of the wiring substrate side and a node of the ground through conductor on the other main surface side of the wiring substrate. That is, the nodes 83 and 84 correspond to the node of the power-side through conductor on the one main surface side of the wiring substrate and the node of the ground through conductor on the one main surface side of the wiring substrate, and the nodes 85 and 86 correspond to the node of the power-side through conductor on the other main surface side of the wiring substrate and the node of the ground through conductor on the other main surface side of the wiring substrate.

As described with reference to FIG. 18, the unit equivalent circuit may include 2×n capacitor equivalent circuits (where n is an integer greater than or equal to 2). Thus, it is possible to reproduce a case where the unit includes, as the capacitor element, 2×n capacitor elements connected in parallel between a pair of the power-side through conductor and the ground-side through conductor. Such a unit can be realized by stacking a plurality of substrates, each of which has a capacitor element built therein, and then forming the through conductors that pass through the substrates all at once. The 2×n capacitor equivalent circuits are connected in parallel with each other, in which n capacitor equivalent circuits are connected to the input port (Port 1) side of the equivalent circuit representing the power-side through conductor and the input port (Port 1) side of the equivalent circuit representing the ground through conductor, and the remaining n capacitor equivalent circuits are connected to the output port (Port 2) side of the equivalent circuit representing the power-side through conductor and the output port (Port 2) side of the equivalent circuit representing the ground through conductor.

FIG. 18 illustrates a case where the number of units connected is 1, but the number of units connected may be 2 or more. In such a case, at least one unit may include the first equivalent circuit 81 and the second equivalent circuit 82 shown in FIG. 18, but it is preferable that all units each include the first equivalent circuit 81 and the second equivalent circuit 82 shown in FIG. 18. In any case, at least a portion of the equivalent circuit G, the equivalent circuit G, the first equivalent circuit 81, and the second equivalent circuit 82 shown in FIG. 18 may be replaced by an alternative parameter corresponding to that portion.

Next, the function of the control unit 20 will be described in detail.

As shown in FIG. 3, the control unit 20 has an input reception unit 21, a calculation unit 22, and an output unit 23.

The input reception unit 21 performs a process of acquiring a pitch that is set by a user, that is between at least one pair of the power-side through conductor and the ground-side through conductor, and that corresponds to (matches) one of a plurality of predetermined pitches. That is, in the substrate design assisting device 1, the user cannot arrange (e.g., design) the power-side through conductor and ground-side through conductor on the wiring substrate at an arbitrary pitch, but can only arrange (design) the power-side through conductor and ground-side through conductor on the wiring substrate at a pitch that matches one of the preset predetermined pitches.

It is noted that the input reception unit 21 can be configured to acquire the pitch that is between each pair of the power-side through conductor and the ground-side through conductor that is set by the user, for example, from their coordinate information.

Further, the input reception unit 21 can be configured to perform a process of acquiring the number of units connected (e.g., the number of units connected in parallel) set by the user.

Note that the number of units connected can be obtained, for example, from the number of pairs of the power-side through conductor and the ground-side through conductor connected in parallel to the same power supply line.

In an exemplary aspect, each pair of the power-side through conductor and the ground-side through conductor are preferably set by the user be located at intersections of a predetermined grid. Thus, a capacitor element with reduced equivalent series resistance (ESR) and equivalent series inductance (ESL) can be arranged.

More specifically, for example, when a first power-side through conductor or ground-side through conductor is arranged by the user via the input unit 10, a predetermined grid in which the through conductor is located at an intersection is displayed on the display unit 40. Here, the type and pitch of the grid can be set (specified) by the user, and the pitch of the grid matches one of a plurality of predetermined pitches between a pair of the power-side through conductor and the ground-side through conductor. The second and subsequent power-side through conductors and ground-side through conductors are set so as to be arranged only at other intersections of the grid. At this time, it is preferable that a pair of the power-side through conductor and the ground-side through conductor be located at adjacent intersections of the grid, but they may be located at non-adjacent intersections of the grid.

FIG. 19 is a schematic diagram showing an example of a grid and power-side through conductors and ground-side through conductors arranged at the intersections of the grid.

In the example shown in FIG. 19, a square grid is displayed, in which power-side through conductors 71 and ground-side through conductors 72 are arranged in a square arrangement. In the square arrangement, the power-side through conductors 71 and the ground-side through conductors 72 are arranged at vertices of the squares. As shown in FIG. 19, the power-side through conductors 71 and the ground-side through conductors 72 may be arranged alternately in the vertical and horizontal directions.

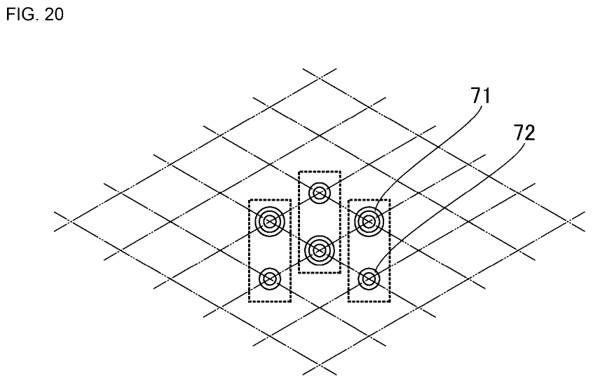

FIG. 20 is a schematic diagram showing another example of a grid and power-side through conductors and ground-side through conductors arranged at the intersections of the grid.

In the example shown in FIG. 20, a diamond grid (with internal angles of 60° and 120°) is displayed, and the power-side through conductors 71 and the ground-side through conductors 72 are arranged in a hexagonal arrangement. In the hexagonal arrangement, the power-side through conductors 71 and the ground-side through conductors 72 are arranged at vertices of regular hexagons and at the centers of the regular hexagons. As shown in FIG. 20, the power-side through conductors 71 and the ground-side through conductors 72 may be arranged alternately in the vertical direction.

In FIGS. 19 and 20, a rectangular dashed line surrounding a pair of the power-side through conductor 71 and the ground-side through conductor 72 is an imaginary line indicating the area of the unit.

The input reception unit 21 further acquires substrate information that is set by the user and that is information about the constituent elements of the substrate excluding the unit. That is, the input reception unit 21 acquires information designed (for example, drawn) by the user about the constituent elements other than the unit. Example of the substrate information include information about the wiring lines, the resin substrate, and the through conductors (such as vias and through holes) not included in the unit. The information about the wiring lines includes, for example, the layout (e.g., coordinates) of the wiring lines and the conductor thickness of the wiring layer. The information about the resin substrate includes, for example, the thickness of the resin substrate portion when the resin substrate is multilayered. The information about the through conductors not included in the unit includes, for example, the coordinates and dimensions of the through conductors.

The substrate information is inputted according to a predetermined design rule. That is, the substrate information set by the user is limited to information that satisfies the design rule. Instead of receiving only the substrate information according to the design rule, it is also possible to verify whether the inputted substrate information satisfies the design rule or not; if there is an item that does not satisfy the design rule, an error will be displayed on the display unit 40 to prompt the user to change the item.

The design rule includes various types of information necessary to form the wiring substrate, such as the conductor thickness of the wiring layer, the L/S rule of the wiring lines, the conductor amount of the through conductor, and the thickness of the resin substrate portion when the resin substrate is multilayered.

The calculation unit 22 Is configured to perform a process of acquiring, from the storage unit 30, circuit information corresponding to the pitch between each pair of the power-side through conductor and the ground-side through conductor and the number of units connected acquired by the input reception unit 21, and calculating the impedance of the power supply line based on the acquired circuit information (e.g., unit equivalent circuit and/or parameter). Since the circuit information corresponding to the pitch can accurately reproduce a unit in which a pair of the power-side through conductor and the ground-side through conductor are arranged at that pitch, the impedance characteristics of the power supply line can be accurately calculated. Further, since such circuit information is prepared for each number of units connected, the calculation accuracy of the impedance characteristics of the power supply line can be increased.

More specifically, the calculation unit 22 is configured to perform a process of calculating the impedance of the power supply line based on the substrate information acquired by the input reception unit 21 in addition to the circuit information corresponding to the pitch and the number of units connected acquired by the input reception unit 21.

At this time, the calculation unit 22 is configured to perform a process of calculating the impedance characteristics of the unit based on the acquired circuit information (e.g., unit equivalent circuit and/or parameter), and performs a process of calculating the impedance characteristics of the substrate (except the unit) based on the acquired substrate information. Further, the calculation unit 22 performs a process of combining both impedance characteristics and calculating the impedance characteristics of the entire substrate in the combined state, which in this case is the impedance characteristics of the power supply line. In an exemplary aspect, SPICE (Simulation Program with Integrated Circuit Emphasis) can be used to perform these calculation processes.

The output unit 23 is configured to perform a process of displaying the impedance of the power supply line, which is the result of the calculation by the calculation unit 22, on the display unit 40.

Next, the operation of the substrate design assisting device 1 (i.e., a substrate design assisting method by the substrate design assisting device 1) will be described.

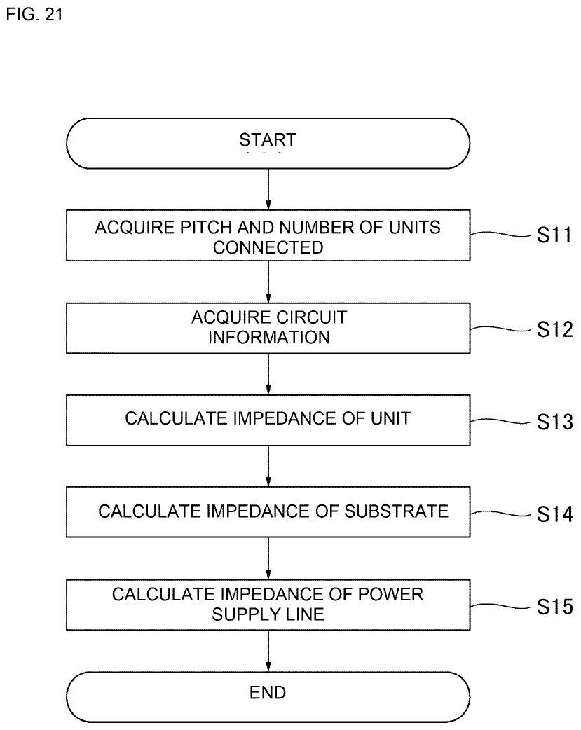

FIG. 21 is a flowchart for explaining an example of the operation of the substrate design assisting device according to exemplary Embodiment 1.

As shown in FIG. 21, first, the input reception unit 21 performs a process of acquiring, through the input unit 10, a pitch that is between at least one pair of the power-side through conductor and the ground-side through conductor and that corresponds to one of a plurality of predetermined pitches, the number of units connected in parallel, and the substrate information (step S11).

Next, the calculation unit 22 performs a process of acquiring, from the storage unit 30, circuit information (e.g., unit equivalent circuit and/or parameter) corresponding to the pitch and the number of units connected acquired in step S11 (step S12).

Next, the calculation unit 22 performs a process of calculating the impedance characteristics of the unit based on the circuit information acquired in step S12 (step S13).

Next, the calculation unit 22 performs a process of calculating the impedance characteristics of the substrate (except the unit) based on the substrate information acquired in step S11 (step S14).

Note that the order of steps S12, S13, and S14 is not particularly limited to this order, but may be performed, for example, in an order of steps S14, S12, and S13, or steps S12 and S13 may be performed in parallel with step S14.

Next, the calculation unit 22 performs a process of combining the impedance characteristics of the unit calculated in step S13 with the impedance characteristics of the substrate (except the unit) calculated in step S14 and calculating the impedance characteristics of the power supply line in the combined state (step S15).

The output unit 23 performs a process of displaying the impedance of the power supply line, which is the result of the calculation performed by the calculation unit 22, on the display unit 40, thereby completing the operation of the substrate design assisting device 1.

Based on the impedance of the power supply line displayed on the display unit 40, the user can increase or decrease, for example, the number of bypass capacitors, i.e., the number of pairs of the power-side through conductor and the ground-side through conductor, or the pitch between a pair of the power-side through conductor and the ground-side through conductor.

As described above, the substrate design assisting device according to the above embodiment is configured to design a power supply line to which a bypass capacitor is connected via a plurality of through conductors.

In the above embodiment, when the circuit information corresponding to the predetermined pitches between the power-side through conductor and the ground-side through conductor and the number of units connected is used has been described, but the circuit information may be set at least for each predetermined pitch. For example, the circuit information may be set according to the number of units connected in addition to the pitch, or may be set according to the capacitance of the capacitor element included in the unit, the number of layers of the wiring substrate, or the like, instead of the number of units connected, in addition to the pitch.

In the above embodiment, the substrate design assisting device is configured as a single device, but each function of the substrate design assisting device may be realized by a distributed processing system appropriately distributed among a plurality of devices. For example, the terminal device used by the user may only input information and display the result of the calculation, and the calculation process of the impedance based on the circuit information or the like corresponding to the input information may be performed by a server device (for example, on the cloud). In such a case, the circuit information may be stored in a storage unit of the server device. Further, for example, the calculation process of the impedance of the unit based on the circuit information and the calculation process of the impedance of the substrate (except the unit) based on the substrate information may be performed by different devices (i.e., the terminal device and the server device).

The following exemplary aspects are disclosed in this description.

<1> A substrate design assisting device is provided that arranges, on a wiring substrate, a bypass capacitor connected to a power supply line and a ground line via at least one pair of a power-side through conductor and a ground-side through conductor. In this aspect, the substrate design assisting device includes a storage unit configured to store circuit information representing a unit that includes a pair of a power-side through conductor and a ground-side through conductor and a capacitor element connected between the power-side through conductor and the ground-side through conductor, for each of a plurality of predetermined pitches between the pair of the power-side through conductor and the ground-side through conductor; an input reception unit configured to acquire a pitch that is set by a user and that corresponds to one of the plurality of predetermined pitches; and a calculation unit configured to acquire, from the storage unit, circuit information corresponding to the pitch acquired by the input reception unit, and to calculate the impedance of the power supply line based on the acquired circuit information. In this aspect, the circuit information stored in the storage unit includes at least one of an equivalent circuit representing the unit and a parameter corresponding to at least a portion of the equivalent circuit representing the unit, and the equivalent circuit representing the unit includes an equivalent circuit representing the capacitor element that includes a capacitance component set according to the corresponding predetermined pitch.

<2> In an exemplary aspect of the substrate design assisting device according to <1>, the equivalent circuit representing the unit includes an inductance component representing the power-side through conductor and an inductance component representing the ground-side through conductor, both inductance components being set regardless of the predetermined pitch.

<3> In an exemplary aspect of the substrate design assisting device according to <1> or <2>, the equivalent circuit representing the unit includes an equivalent circuit representing the power-side through conductor and an equivalent circuit representing the ground-side through conductor, the equivalent circuit representing the power-side through conductor includes a first circuit portion and a second circuit portion connected in series between an input port and an output port, the equivalent circuit representing the ground-side through conductor includes a third circuit portion and a fourth circuit portion connected in series between the input port and the output port, and the equivalent circuit representing the capacitor element is connected to a node between the first circuit portion and the second circuit portion and a node between the third circuit portion and the fourth circuit portion.

<4> In an exemplary aspect of the substrate design assisting device according to any one of <1> to <3>, the equivalent circuit representing the capacitor element includes a ladder circuit.

<5> In an exemplary aspect of the substrate design assisting device according to <4>, the ladder circuit includes, as the capacitor component, two or more capacitance components.

<6> In an exemplary aspect of the substrate design assisting device according to any one of <1> to <5>, the unit includes, as the capacitor element, a first capacitor element and a second capacitor element connected in parallel between the pair of the power-side through conductor and the ground-side through conductor, the equivalent circuit representing the unit includes, as the equivalent circuit representing the capacitor element, a first equivalent circuit representing the first capacitor element and a second equivalent circuit representing the second capacitor element, the first equivalent circuit and the second equivalent circuit are equivalent to each other, the first equivalent circuit is connected to a node of the power-side through conductor on one main surface side of the wiring substrate and a node of the ground through conductor on the one main surface side of the wiring substrate, and the second equivalent circuit is connected to a node of the power-side through conductor on the other main surface side of the wiring substrate and a node of the ground through conductor on the other main surface side of the wiring substrate.

<7> In an exemplary aspect of the substrate design assisting device according to any one of <1> to <6>, the equivalent circuit representing the capacitor element includes an equivalent circuit portion that reaches the capacitance component after passing through an LR circuit.

<8> In an exemplary aspect of the substrate design assisting device according to any one of <1> to <7>, the unit includes, as the capacitor element, 2×n capacitor elements connected in parallel between the pair of the power-side through conductor and the ground-side through conductor, and the equivalent circuit representing the unit includes 2×n equivalent circuits representing the capacitor elements, and n is an integer greater than or equal to 2.

<9> In an exemplary aspect of the substrate design assisting device according to any one of <1> to <8>, each pair of the power-side through conductor and the ground-side through conductor set by the user is located at intersections of a predetermined grid.

<10> In an exemplary aspect of the substrate design assisting device according to any one of <1> to <9>, the input reception unit further acquires substrate information that is set by the user and that is information about constituent elements of the substrate excluding the unit, and the calculation unit calculates the impedance of the power supply line based on the circuit information and the substrate information acquired by the input reception unit.

<11> In an exemplary aspect of the substrate design assisting device according to any one of <1> to <10>, the storage unit stores the circuit information representing the unit according to the number of units connected in parallel, the input reception unit further acquires the number of units connected set by the user, and the calculation unit acquires, from the storage unit, circuit information corresponding to the pitch and the number of units connected acquired by the input reception unit, and calculates the impedance of the power supply line based on the acquired circuit information.

<12> A substrate design assisting system is provided that arranges, on a wiring substrate, a bypass capacitor connected to a power supply line and a ground line via at least one pair of a power-side through conductor and a ground-side through conductor. In this aspect, the substrate design assisting system includes a storage unit configured to store circuit information representing a unit that includes a pair of a power-side through conductor and a ground-side through conductor and a capacitor element connected between the power-side through conductor and the ground-side through conductor, for each of a plurality of predetermined pitches between the pair of the power-side through conductor and the ground-side through conductor; an input reception unit configured to acquire a pitch that is set by a user and that corresponds to one of the plurality of predetermined pitches; and a calculation unit configured to acquire, from the storage unit, circuit information corresponding to the pitch acquired by the input reception unit, and calculates the impedance of the power supply line based on the acquired circuit information. In this aspect, the circuit information stored in the storage unit includes at least one of an equivalent circuit representing the unit and a parameter corresponding to at least a portion of the equivalent circuit representing the unit, and the equivalent circuit representing the unit includes an equivalent circuit representing the capacitor element that includes a capacitance component set according to the corresponding predetermined pitch.

<13> A data structure is provided that is related to circuit information used in a substrate design assisting device or a substrate design assisting system that comprises an input reception unit, a storage unit, and a calculation unit and that assists in arranging, on a wiring substrate, a bypass capacitor connected to a power supply line and a ground line via at least one pair of a power-side through conductor and a ground-side through conductor. In this aspect, the data structure is related to circuit information stored in the storage unit and includes circuit information representing a unit that includes a pair of a power-side through conductor and a ground-side through conductor and a capacitor element connected between the pair of the power-side through conductor and the ground-side through conductor, for each of a plurality of predetermined pitches between the pair of the power-side through conductor and the ground-side through conductor. In this aspect, the data structure is used for a process in which the calculation unit acquires, based on a pitch acquired by the input reception unit, circuit information corresponding to the pitch acquired by the input reception unit from the storage unit, and calculates the impedance of the power supply line based on the acquired circuit information. Moreover, the pitch is a pitch that is set by the user, that is between at least one pair of a power-side through conductor and a ground-side through conductor, and that corresponds to one of the plurality of predetermined pitches, the circuit information includes at least one of an equivalent circuit representing the unit and a parameter corresponding to at least a portion of the equivalent circuit representing the unit, and the equivalent circuit representing the unit includes an equivalent circuit representing the capacitor element that includes a capacitance component set according to the corresponding predetermined pitch.

### REFERENCE SIGNS LIST

1 substrate design assisting device
10 input unit
20 control unit
21 input reception unit
22 calculation unit
23 output unit
30 storage unit
40 display unit
50, 80 unit equivalent circuit
51, 52, 83, 84, 85, 86 node
60 capacitor equivalent circuit
61 first terminal
62 second terminal
63 first capacitance portion
64 second capacitance portion
65 LR circuit
71 power-side through conductor
72 ground-side through conductor
81 first equivalent circuit
82 second equivalent circuit
101 capacitor portion
110 capacitor element
111 anode plate
111A core portion
111B porous portion
112 cathode layer
113 dielectric layer
120 through conductor
120A cathode through conductor
120B anode through conductor
125A, 125B resin filling portion
130 sealing layer
140A, 140B conductor wiring layer
145 via conductor

What is claimed:

1. A substrate design assisting device for arranging, on a wiring substrate, a bypass capacitor connected to a power supply line and a ground line via at least one pair of a power-side through conductor and a ground-side through conductor, the substrate design assisting device comprising:
a storage unit configured to store circuit information representing a unit that includes a pair of a power-side through conductor and a ground-side through conductor and a capacitor element connected between the power-side through conductor and the ground-side through conductor, for each of a plurality of predetermined pitches between the pair of the power-side through conductor and the ground-side through conductor;
an input reception unit configured to acquire a pitch set by a user and that corresponds to one predetermined pitch of the plurality of predetermined pitches; and
a calculation unit configured to acquire, from the storage unit, circuit information corresponding to the pitch acquired by the input reception unit, and to calculate an impedance of the power supply line based on the acquired circuit information,
wherein the circuit information stored in the storage unit includes at least one of an equivalent circuit representing the unit and a parameter corresponding to at least a portion of the equivalent circuit representing the unit, and
wherein the equivalent circuit representing the unit includes an equivalent circuit representing the capacitor element that includes a capacitance component set according to the one predetermined pitch.

2. The substrate design assisting device according to claim 1, wherein the equivalent circuit representing the unit includes an inductance component representing the power-side through conductor and an inductance component representing the ground-side through conductor, both inductance components being independent of the predetermined pitch.

3. The substrate design assisting device according to claim 1, wherein:
the equivalent circuit representing the unit includes an equivalent circuit representing the power-side through conductor and an equivalent circuit representing the ground-side through conductor,
the equivalent circuit representing the power-side through conductor includes a first circuit portion and a second circuit portion connected in series between an input port and an output port,
the equivalent circuit representing the ground-side through conductor includes a third circuit portion and a fourth circuit portion connected in series between the input port and the output port, and
the equivalent circuit representing the capacitor element is connected to a node between the first circuit portion and the second circuit portion and a node between the third circuit portion and the fourth circuit portion.

4. The substrate design assisting device according to claim 1, wherein the equivalent circuit representing the capacitor element includes a ladder circuit.

5. The substrate design assisting device according to claim 4, wherein the ladder circuit includes two or more capacitance components.

6. The substrate design assisting device according to claim 1, wherein:
the unit includes a first capacitor element and a second capacitor element that comprise the capacitor element and that are connected in parallel between the power-side through conductor and the ground-side through conductor,
the equivalent circuit representing the unit includes a first equivalent circuit representing the first capacitor element and a second equivalent circuit representing the second capacitor element,
the first equivalent circuit and the second equivalent circuit are equivalent to each other,
the first equivalent circuit is connected to a node of the power-side through conductor on a first main surface side of the wiring substrate and a node of the ground through conductor on the first main surface side of the wiring substrate, and
the second equivalent circuit is connected to a node of the power-side through conductor on a second main surface side of the wiring substrate and a node of the ground through conductor on the second main surface side of the wiring substrate.

7. The substrate design assisting device according to claim 1, wherein the equivalent circuit representing the capacitor element includes an equivalent circuit portion that reaches the capacitance component after passing through an LR circuit.

8. The substrate design assisting device according to claim 1, wherein:
the unit includes, as the capacitor element, 2×n capacitor elements connected in parallel between the power-side through conductor and the ground-side through conductor,
the equivalent circuit representing the unit includes 2×n equivalent circuits representing the capacitor elements, and
n is an integer greater than or equal to 2.

9. The substrate design assisting device according to claim 1, wherein each pair of the power-side through conductor and the ground-side through conductor set by the user is located at intersections of a predetermined grid.

10. The substrate design assisting device according to claim 1, wherein:
the input reception unit is further configured to acquire substrate information that is set by the user and that comprises information relating to constituent elements of the substrate, and
the calculation unit is configured to calculate the impedance of the power supply line based on the circuit information and the substrate information acquired by the input reception unit.

11. The substrate design assisting device according to claim 1, wherein:
the storage unit is configured to store the circuit information representing the unit according to a number of units connected in parallel,
the input reception unit is further configured to acquire the number of units connected in parallel as set by the user, and
the calculation unit is further configured to acquire, from the storage unit, circuit information corresponding to the pitch and the number of units acquired by the input reception unit, and to calculate the impedance of the power supply line based on the acquired circuit information.

12. A substrate design assisting system for arranging, on a wiring substrate, a bypass capacitor connected to a power supply line and a ground line via at least one pair of a power-side through conductor and a ground-side through conductor, the substrate design assisting system comprising:
a storage unit configured to store circuit information representing a unit that includes a pair of a power-side through conductor and a ground-side through conductor and a capacitor element connected between the power-side through conductor and the ground-side through conductor, for each of a plurality of predetermined pitches between the pair of the power-side through conductor and the ground-side through conductor;
an input reception unit configured to acquire a pitch set by a user and that corresponds to one predetermined pitch of the plurality of predetermined pitches; and
a calculation unit configured to acquire, from the storage unit, circuit information corresponding to the pitch acquired by the input reception unit, and to calculate the impedance of the power supply line based on the acquired circuit information,
wherein the circuit information stored in the storage unit includes at least one of an equivalent circuit representing the unit and a parameter corresponding to at least a portion of the equivalent circuit representing the unit, and
wherein the equivalent circuit representing the unit includes an equivalent circuit representing the capacitor element that includes a capacitance component set according to the one predetermined pitch.

13. The substrate design assisting system according to claim 12, wherein the equivalent circuit representing the unit includes an inductance component representing the power-side through conductor and an inductance component representing the ground-side through conductor, both inductance components being independent of the predetermined pitch.

14. The substrate design assisting system according to claim 12, wherein:
the equivalent circuit representing the unit includes an equivalent circuit representing the power-side through conductor and an equivalent circuit representing the ground-side through conductor,
the equivalent circuit representing the power-side through conductor includes a first circuit portion and a second circuit portion connected in series between an input port and an output port,
the equivalent circuit representing the ground-side through conductor includes a third circuit portion and a fourth circuit portion connected in series between the input port and the output port, and
the equivalent circuit representing the capacitor element is connected to a node between the first circuit portion and the second circuit portion and a node between the third circuit portion and the fourth circuit portion.

15. The substrate design assisting system according to claim 12, wherein the equivalent circuit representing the capacitor element includes a ladder circuit.

16. The substrate design assisting system according to claim 15, wherein the ladder circuit includes two or more capacitance components.

17. The substrate design assisting system according to claim 12, wherein:
the unit includes a first capacitor element and a second capacitor element that comprise the capacitor element and that are connected in parallel between the power-side through conductor and the ground-side through conductor,
the equivalent circuit representing the unit includes a first equivalent circuit representing the first capacitor element and a second equivalent circuit representing the second capacitor element,
the first equivalent circuit and the second equivalent circuit are equivalent to each other,
the first equivalent circuit is connected to a node of the power-side through conductor on a first main surface side of the wiring substrate and a node of the ground through conductor on the first main surface side of the wiring substrate, and
the second equivalent circuit is connected to a node of the power-side through conductor on a second main surface side of the wiring substrate and a node of the ground through conductor on the second main surface side of the wiring substrate.

18. The substrate design assisting system according to claim 12, wherein the equivalent circuit representing the capacitor element includes an equivalent circuit portion that reaches the capacitance component after passing through an LR circuit.

19. The substrate design assisting system according to claim 12, wherein:
the unit includes, as the capacitor element, 2×n capacitor elements connected in parallel between the power-side through conductor and the ground-side through conductor,
the equivalent circuit representing the unit includes 2×n equivalent circuits representing the capacitor elements, and
n is an integer greater than or equal to 2.

20. A substrate design assisting method for arranging, on a wiring substrate, a bypass capacitor connected to a power supply line and a ground line via at least one pair of a power-side through conductor and a ground-side through conductor, the method comprising:
storing, by a storage unit, circuit information representing a unit that includes a pair of a power-side through conductor and a ground-side through conductor and a capacitor element connected between the power-side through conductor and the ground-side through conductor, for each of a plurality of predetermined pitches between the pair of the power-side through conductor and the ground-side through conductor;
acquiring a pitch set by a user and that corresponds to one predetermined pitch of the plurality of predetermined pitches;
acquiring, from the storage unit, circuit information corresponding to the acquired pitch;
calculating an impedance of the power supply line based on the acquired circuit information; and
storing the circuit information to include at least one of an equivalent circuit representing the unit and a parameter corresponding to at least a portion of the equivalent circuit representing the unit,
wherein the equivalent circuit representing the unit includes an equivalent circuit representing the capacitor element that includes a capacitance component set according to the one predetermined pitch.
